(19) United States
(12) Patent Application Publication
(10) Pub. No.: US 2024/0313270 A1
(43) Pub. Date: Sep. 19, 2024

(54) BATTERY DEVICE, CONTROL METHOD, AND CONTROL PROGRAM

(71) Applicant: Renesas Electronics Corporation, Tokyo (JP)

(72) Inventors: Masaki HOGARI, Tokyo (JP); Hirofumi MAEDA, Tokyo (JP); Hiroshi TADOKORO, Tokyo (JP); Kenji NOGUCHI, Tokyo (JP); Hiroyasu KOIKE, Tokyo (JP)

(73) Assignee: Renesas Electronics Corporation, Tokyo (JP)

(21) Appl. No.: 18/607,397

(22) Filed: Mar. 15, 2024

(30) Foreign Application Priority Data
Mar. 15, 2023 (JP) 2023-040407

(51) Int. Cl. H01M 10/42; G01R 31/382; G01R 31/392; H01M 10/04; H01M 10/0525; H01M 10/48

(52) U.S. Cl. CPC H01M 10/4257; G01R 31/382; G01R 31/392; H01M 10/486; H01M 10/0422; H01M 10/0525; H01M 2010/4271

(57) ABSTRACT

A battery device is disclosed. The battery device includes a lithium-ion battery cell; a strain gauge attached to a surface of the battery cell; a temperature sensor detecting a temperature of the battery cell; and a measurement device calculating an SOC (State of Charge) of the battery cell a strain amount based on the temperature detected by the temperature sensor and a strain amount of the strain gauge changed according to a volume change due to charge and discharge of the battery cell.

### CROSS-REFERENCE TO RELATED APPLICATION

The present application claims priority under 35 U.S.C. § 119 to Japanese Patent Application No. 2023-040407 filed on Mar. 15, 2023. The disclosure of Japanese Patent Application No. 2023-040407, including the specification, drawings and abstract is incorporated herein by reference in its entirety.

### BACKGROUND

The present invention relates to a battery device, a control method, and a control program, more particularly, to a battery device, a control method, and a control program suitable for accurately measuring SOC of a lithium-ion battery cell.

There is a disclosed technique listed below.

[Patent Document 1] Japanese Unexamined Patent Application Publication No. 2022-171118

In recent years, development of measurement devices that measure SOC (State of Charge) of lithium-ion batteries has been progressing. A technique related to the measurement of the SOC of a battery is disclosed in Patent Document 1, for example.

### SUMMARY

The measurement devices still require to measure the SOC of the lithium-ion batteries with higher accuracy. Other problems and novel features will become apparent from the description of the present specification and the accompanying drawings.

A battery device according to the present disclosure includes: a lithium-ion battery cell; a strain gauge attached to a surface of the battery cell; a temperature sensor detecting a temperature of the battery cell; and a measurement device calculating SOC (State of Charge) of the battery cell based on the temperature detected by the temperature sensor and a strain amount of the strain gauge changed according to a volume change due to charge and discharge of the battery cell.

A control method according to the present disclosure is performed by a measurement device of a batter device, in which the battery device including: a lithium-ion battery cell; a strain gauge attached to a surface of the battery cell; a temperature sensor; and the measurement device, and in which the method comprises: using the measurement device of the battery to detect a temperature of the battery cell; detecting a strain amount of the strain gauge changed according to a volume change due to charge and discharge of the battery cell; based on the temperature of the battery cell and the strain amount of the strain gauge, calculating an SOC (State Of Charge) of the battery cell.

A computer readable storage medium according to the present disclosure causes a computer to perform a control processing by a measurement device of a battery device, the battery device includes: a lithium-ion battery cell; a strain gauge attached to a surface of the battery cell; a temperature sensor; and the measurement device, in which the computer readable storage medium causes the computer to perform: a processing of using the temperature sensor to detect a temperature of the battery cell; a processing of detecting a strain amount of the strain gauge changed according to a volume change due to charge and discharge of the battery cell; a processing of calculating SOC (State Of Charge) of the battery cell based on the temperature of the battery cell and the strain amount of the strain gauge.

The present disclosure can provide a battery device, a control method, and a control program that can accurately measure the SOC of the lithium-ion battery cell.

### BRIEF DESCRIPTION OF THE DRAWINGS

FIG. 1 is a diagram showing a configuration example of a battery device according to a first embodiment.

FIG. 2 is a conceptual diagram showing an internal structure of a battery cell provided in the battery device according to the first embodiment during discharge.

FIG. 3 is a conceptual diagram showing an internal structure of the battery cell provided in the battery device according to the first embodiment during charge.

FIG. 4 is a diagram showing an example of the battery cell and a strain gauge attached to the battery cell.

FIG. 5 is a schematic perspective view showing one example of the battery device according to the first embodiment.

FIG. 6 is a flowchart showing a flow of an acquisition processing of temperature characteristic parameters of a pressure detected by a strain gauge, which is performed before actual operations by a measurement device provided in the battery device according to the first embodiment.

FIG. 7 is a diagram showing a relationship between a temperature detected by a temperature sensor and the pressure detected by the strain gauge.

FIG. 8 is a flowchart showing the flow of the acquisition processing of SOC parameters, which is performed before the actual operations by the measurement device provided in the battery device according to the first embodiment.

FIG. 9 is a flowchart showing one example of an SOC measurement processing performed during the actual operations by the measurement device provided in the battery device according to the first embodiment.

FIG. 10 is a diagram showing a relationship between the pressure detected by the strain gauge and the SOC of the battery cell before and after canceling temperature characteristics.

FIG. 11 is a timing chart showing changes in pressures applied to the strain gauge from battery cells that is repeatedly charged and discharged.

FIG. 12 is a diagram showing one example of a layout of strain gauges attached to battery cells of a battery device according to a second embodiment.

FIG. 13 is a diagram showing one example of the layout of the strain gauges attached to the battery cells of the battery device according to the second embodiment.

FIG. 14 is a diagram showing one example of the layout of the strain gauges attached to the battery cells of the battery device according to the second embodiment.

FIG. 15 is a diagram showing one example of the layout of the strain gauges attached to the battery cells of the battery device according to the second embodiment.

FIG. 16 is a diagram showing one example of the layout of the strain gauges attached to the battery cells of the battery device according to the second embodiment.

FIG. 17 is a diagram showing an appearance of a laminate-shaped battery cell.

FIG. 18 is a diagram showing an internal structure of the laminate-shaped battery cell.

### DETAILED DESCRIPTION

Embodiments will be described below with reference to the drawings. Note that since the drawings are simplified, a technical scope of the embodiments should not be interpreted narrowly based on the descriptions in the drawings. In addition, the same elements are given the same reference numerals, and a redundant description thereof will be omitted.

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof. Also, in the embodiments described below, when referring to the number of elements (including number of pieces, values, amount, range, and the like), the number of the elements is not limited to a specific number unless otherwise stated or except the case where the number is apparently limited to a specific number in principle, and the number larger or smaller than the specified number is also applicable.

Further, in the embodiments described below, it goes without saying that the components (including element steps) are not always indispensable unless otherwise stated or except the case where the components are apparently indispensable in principle. Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value (including number of pieces, values, amount, range, and the like) described above.

### First Embodiment

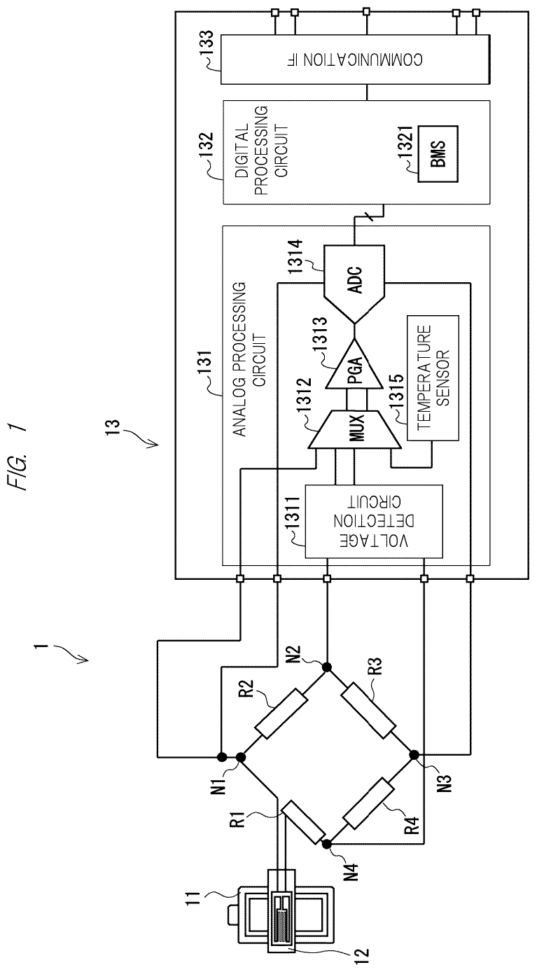

FIG. 1 is a diagram showing a configuration example of a battery device 1 according to a first embodiment. The battery device 1 includes a battery cell 11, a strain gauge 12, a measurement device 13, and a coupling member 14 (not shown). The strain gauge 12 can also be said to be part of the measurement device 13. The battery cell 11, strain gauge 12, measurement device 13, and coupling member 14 may be packaged in a casing (not shown).

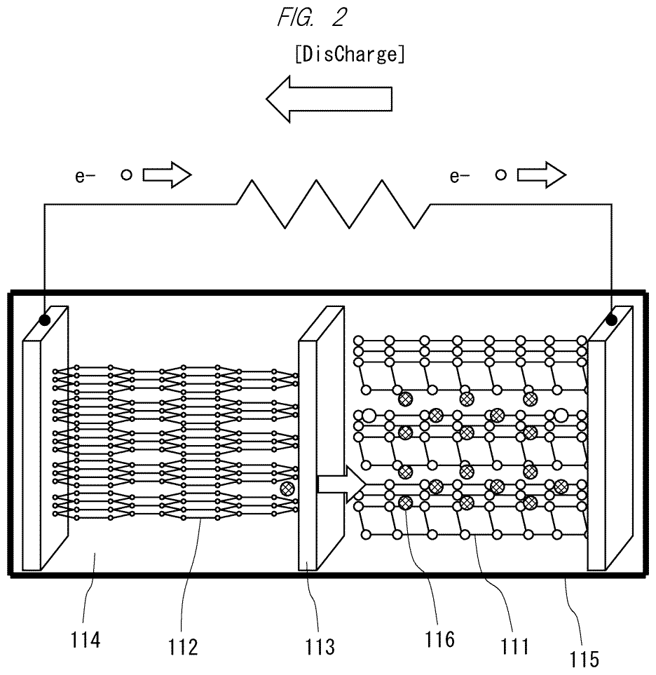

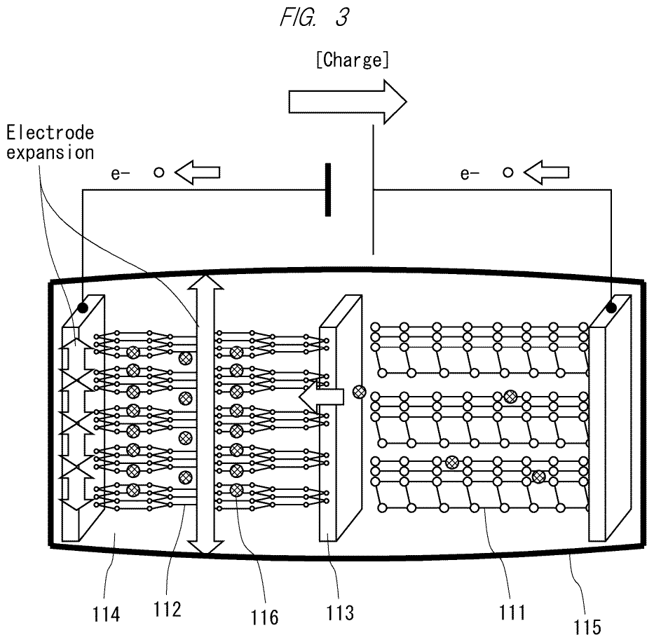

The battery cell 11 is a lithium-ion battery cell. FIG. 2 is a conceptual diagram showing an internal structure of the battery cell 11 during discharge. FIG. 3 is a conceptual diagram showing an internal structure of the battery cell 11 during charge.

As shown in FIGS. 2 and 3, the battery cell 11 includes, inside a casing 115, a positive electrode layer 111 formed with a positive electrode active material, a negative electrode layer 112 formed with a negative electrode active material, and a separator 113 provided between the positive electrode layer 111 and the negative electrode layer 112, and an electrolytic solution 114 immersing them. Here, as shown in FIG. 2, during discharge of the battery cell 11, lithium ions 116 remain in the positive electrode layer 111, so that a volume of the negative electrode layer 112 does not expand. In contrast, as shown in FIG. 3, during charge of the battery cell 11, the lithium ions 116 of the positive electrode layer 111 move to the negative electrode layer 112 and are inserted into the negative electrode active material, so that a volume of the negative electrode layer 112 expands.

In FIG. 1, the strain gauge 12 is attached to a surface of the battery cell 11. For example, the strain gauge 12 is attached (integrally formed) to a resin surface of the battery cell 11 by printing (vapor depositing). This reduces the number of parts in the battery device 1, thereby reducing costs. The strain gauge 12 may be covered with a protective film made of a resin, for example.

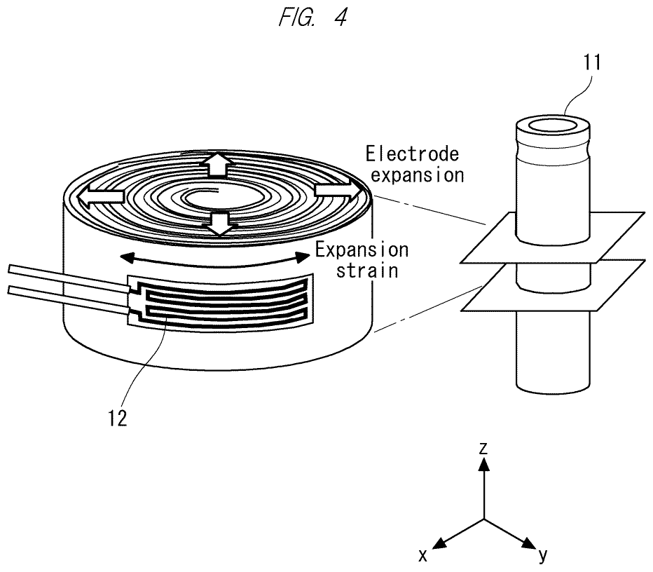

FIG. 4 is a diagram showing one example of the battery cell 11 and the strain gauge 12 attached to the battery cell 11. As shown in FIG. 4, the strain gauge 12 is attached to a side surface of the cylindrical battery cell 11 along a circumferential direction. This is because the battery cell 11 changes more easily in a radial direction (any direction on an x-y plane) than in an axial direction (z-axis direction) according to volume expansion of the battery cell 11 during charge. Note that the strain gauge 12 may be attached to a bottom surface of the cylindrical battery cell 11 (for example, a bottom surface on a negative electrode side where the negative electrode active material is predominant).

In FIG. 1, the measurement device 13 measures SOC (State of Charge) which is a charge rate of the battery cell 11. Here, the measurement device 13 is miniaturized by using an IC (Integrated Circuit). Consequently, the measurement device 13 can be arranged close to the battery cell 11. Therefore, the measurement device 13 is arranged close to the battery cell 11. For example, the measurement device 13 is arranged adjacent to the battery cell 11.

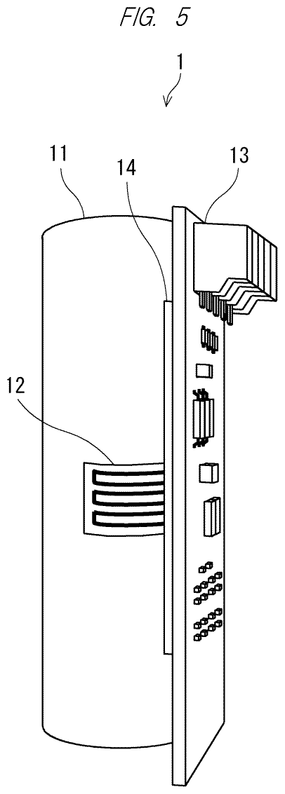

FIG. 5 is a schematic perspective view showing one example of the battery cell 11 and the measurement device 13. As shown in FIG. 5, a printed board on which the measurement device 13 is formed is arranged close to the battery cell 11. Further, the printed board, on which the measurement device 13 is formed, and the battery cell 11 are thermally coupled by the coupling member 14 made of a resin containing at least one of silicone, silicone, and acrylic. Therefore, it can be said that the battery cell 11 and the measurement device 13 operate under substantially the same temperature conditions.

In FIG. 1, the measurement device 13 includes resistance elements R1 to R4, an analog processing circuit 131, a digital processing circuit 132, and a communication interface (communication IF) 133.

One end of the resistance element R1 is connected to one end of the strain gauge 12, and the other end of the resistance element R1 is connected to one end of the resistance element R4 via a node N4. The other end of the resistance element R4 is connected to one end of the resistance element R3 via a node N3. The other end of the resistance element R3 is connected to one end of the resistance element R2 via a node a N2. The other end of the resistance element R2 is connected to the other end of the strain gauge 12 via a node N1. In other words, the strain gauge 12 and the resistance elements R1 to R4 configure a Wheatstone bridge circuit.

Here, when the strain gauge 12 is distorted due to deformation due to the charge and discharge of the battery cell 11, a resistance value of the strain gauge 12 changes. Hereinafter, a pressure that the battery cell 11 receives due to the charge and discharge may be referred to as a pressure P, and a strain amount of the strain gauge 12 changed according to a volume change due to the charge and discharge of the battery cell 11 may be referred to as a strain amount S.

For example, when a volume of the battery cell 11 expands due to the charge and a deformation amount of the battery cell 11 becomes large, the strain amount of the strain gauge 12 increases accordingly, so that the resistance value of the strain gauge 12 increases. Consequently, a potential of the node N4 lowers. In contrast, when the volume of the battery cell 11 contracts due to the discharge and the deformation amount of the battery cell 11 becomes small, the strain amount of the strain gauge 12 becomes small accordingly, so that the resistance value of the strain gauge 12 becomes small. Therefore, the potential of the node N4 rises.

That is, the Wheatstone bridge circuit converts the strain amount (resistance value) of the strain gauge 12 according to the deformation of the battery cell 11 due to the charge and discharge into a potential difference between the nodes N2 and N4 and outputs it.

The analog processing circuit 131 includes a voltage detection circuit 1311, a multiplexer (MUX) 1312, a programmable amplifier (PGA) 1313, an AD converter (ADC) 1314, and a temperature sensor 1315. The voltage detection circuit 1311 detects the potential difference between the nodes N2 and N4 of the Wheatstone bridge circuit. The multiplexer 1312 selectively outputs either a detection result of the voltage detection circuit 1311 or a detection result of the temperature sensor 1315. The programmable amplifier 1313 amplifies an output of the multiplexer 1312 and outputs it. The AD converter 1314 converts an output signal (analog signal) of the programmable amplifier 1313 into a digital signal, and outputs it.

The temperature sensor 1315 detects a temperature T of the measurement device 13. Here, as described above, the battery cell 11 and the measurement device 13 are operating under substantially the same temperature conditions. Therefore, it can be said that the temperature sensor 1315 detects the temperature of the battery cell 11. The temperature sensor 1315 is not limited to being provided within the analog processing circuit 131, and may be provided so as to contact with the battery cell 11, for example.

The digital processing circuit 132 includes at least a BMS 1321. The BMS is an abbreviation for Battery Management System. The BMS 1321 calculates the SOC, which is a charge rate of the battery cell 11 by performing a predetermined arithmetic processing to the digital signal (digital signal corresponding to the potential difference between the nodes N2 and N4 of the Wheatstone bridge circuit) outputted from the analog processing circuit 131. Note that the digital processing circuit 132 is configured to be able to acquire not only an output voltage of the Wheatstone circuit but also a voltage, current, temperature (detection result of the temperature sensor 1315), and the like of the battery cell.

Here, in the digital processing circuit 132, the BMS 1321 calculates the SOC of the battery cell 11, in which an error component(s) due to the temperature has been canceled, by referring to the detection result of the temperature sensor 1315. Note that the arithmetic processing necessary for SOC calculation may be performed by a not-shown MCU (Micro Controller Unit) provided outside the measurement device 13. Alternatively, in the digital processing circuit 132, the BMS 1321 may extract the SOC according to the temperature T detected by the temperature sensor 1315 and the strain amount S of the strain gauge 12 from a table (table database), which stores information representing a relationship between the strain amount S corresponding to the temperature T and the SOC, and output it as a measurement result. Note that the strain amount S in the table may be replaced with the pressure P, which the battery cell 11 receives due to the charge and discharge, and an output voltage of the Wheatstone bridge, which have a correlation.

This makes it possible to accurately calculate the SOC of the battery cell 11 regardless of the temperature. In particular, in this embodiment, the battery cell 11 and the measurement device 13 are arranged close to each other, and the battery cell 11 and the measurement device 13 are thermally coupled by the coupling member 14, so that it can be assumed that the battery cells 11 and the measurement device 13 operate under substantially the same temperature conditions. As a result, a burden of the arithmetic processing necessary for cancelling the error component of the SOC due to the temperature is reduced in comparison with case where the battery cell 11 and the measurement device 13 operate under mutually different temperature conditions.

Information on the SOC of the battery cell 11 calculated by the digital processing circuit 132 is transmitted to an external device via the communication interface 133. Details of a measurement method of the SOC of the battery cell 11 by using the measurement device 13 will be described later.

Note that the measurement device 13 is not limited to the above-mentioned components, and may further include a control circuit that sets and the like various parameters before the actual operation, and a database (table) and the like that store information representing a relationship between the temperature T, the strain amount S, and the SOC.

### Operation of Battery Device 1

Subsequently, a measurement method of the SOC of the battery cell 11 by the measurement device 13 will be detailed.

### Previous Acquisition of Temperature Characteristic Parameter

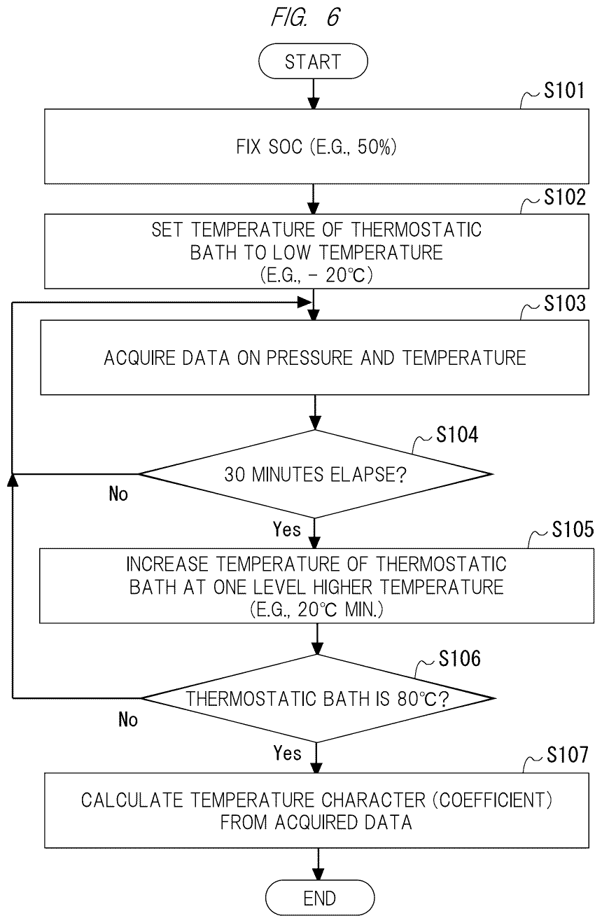

FIG. 6 is a flowchart showing one example of an acquisition processing of the temperature characteristic parameters of the pressure P, which is performed by the measurement device 13 before the actual operation. Note that the acquisition processing of the temperature characteristic parameters of the pressure P, which is performed before the actual operation, is performed with the battery device 1 installed in a thermostatic bath. Note that in the following description, the pressure P that the battery cell 11 receives due to the charge and discharge may be replaced by the strain amount S of the strain gauge 12 or the output voltage of the Wheatstone bridge.

First, the SOC of the battery cell 11 is fixed at a predetermined rate (for example, 50%) (step S101).

Thereafter, a temperature of the thermostatic bath in which the battery device 1 is installed is set to a low temperature (step S102). For example, the temperature of the thermostatic bath is set to −20° C.

Thereafter, the measurement device 13 acquires data on the pressure P that the battery cell 11 receives and the temperature T detected by the temperature sensor 1315 (step S103). The acquisition of the data on the pressure P and the temperature T by the measurement device 13 is repeated for a predetermined period of time (for example, 30 minutes) (step S103->NO in step S104).

When the predetermined period of time has elapsed (YES in step S104), the temperature of the thermostatic bath is set to one level higher temperature (step S105). For example, the temperature of the thermostatic bath is set to be 20° C. higher temperature. Specifically, if the temperature of the thermostatic bath previously before was −20° C., the temperature of the thermostatic bath is set to 0° C.

Thereafter, the measurement device 13 acquires the data on the pressure P and the temperature T (step S103->NO in step S106). The acquisition of the data on the pressure P and the temperature T by the measurement device 13 is performed periodically during a predetermined period of time (for example, 30 minutes) (step S103->No in step S104).

When the predetermined period of time has elapsed (YES in step S104), the temperature of the thermostatic bath is set to one level higher temperature (step S105). For example, the temperature of the thermostatic bath is set to a temperature of 20° C. higher than a current setting temperature. For example, when the current setting temperature of the thermostatic bath is 0° C., the temperature of the thermostatic bath is set to 20° C.

Such processings of steps S103 to S106 are repeated until the temperature of the thermostatic bath reaches an upper limit temperature (for example, 80° C.). Then, when the temperature of the thermostatic chamber reaches the upper limit (YES in step S106), the measurement device 13 finishes acquiring data on the pressure P and the temperature T and, from the acquired data, calculates a temperature characteristic (coefficient) representing a relationship between a pressure P and a pressure P of a predetermined charge rate, that is, a temperature characteristic parameter of the pressure P (step S107).

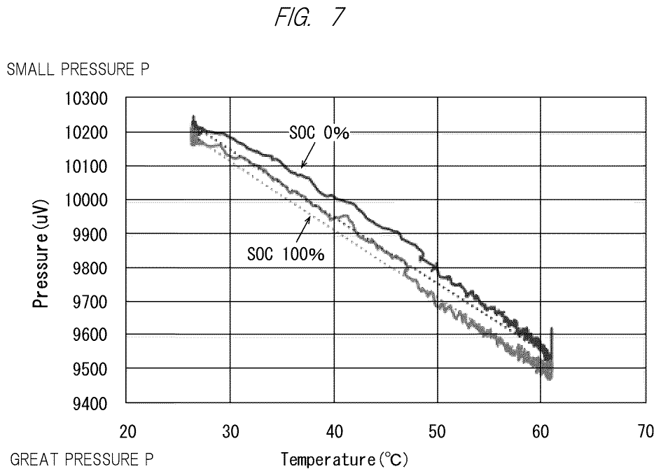

FIG. 7 is a diagram showing a relationship between the temperature T and the pressure P. An example of FIG. 7 shows the temperature characteristics of the pressure P when the SOC of the battery cell 11 is fixed at 0%, and the temperature characteristics of the pressure P when the SOC is set to 100%. In FIG. 7, a horizontal axis represents temperature, and a vertical axis represents an output voltage of the Wheatstone bridge corresponding to the pressure P. Therefore, on the vertical axis, as the output voltage increases, the pressure P decreases (that is, the strain amount S decreases), and as the output voltage decreases, the pressure P increases (that is, the strain amount S increases). Accordingly, referring to FIG. 7, in a case where the pressure P (strain amount) is the same, the SOC becomes lower as the temperature T becomes higher, and the SOC becomes higher as the temperature T becomes lower. Further, in a case where the temperature T is the same, the SOC becomes higher as the pressure P (strain amount S) becomes larger, and the SOC becomes lower as the pressure P (strain amount) becomes smaller.

### Previous Acquisition of SOC Parameter

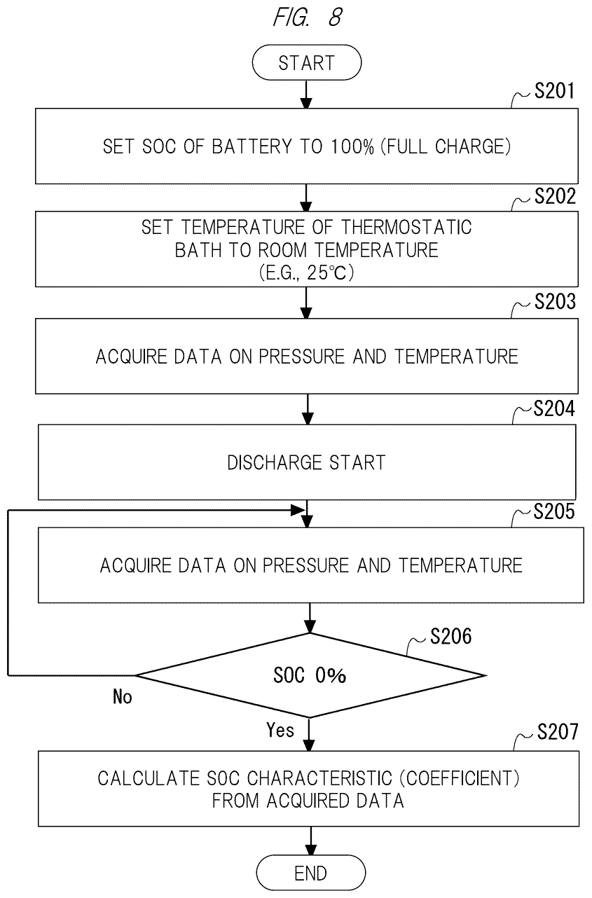

FIG. 8 is a flowchart showing a flow of a previous acquisition processing of SOC parameters performed by the measurement device 13 before actual operations. Note that the previous acquisition processing of the SOC parameters performed before the actual operations is performed with the battery device 1 installed in the thermostatic bath.

First, the SOC of the battery cell 11 is set to 100% (step S201). In other words, the battery cell 11 is set to a fully charged state.

Thereafter, the temperature of the thermostatic bath in which the battery device 1 is installed is set to a room temperature (step S202). For example, the temperature of the thermostatic bath is set to 25° C.

Then, the measurement device 13 acquires the data on the pressure P and the temperature T when the battery cell 11 is fully charged (step S203).

Thereafter, the discharge of the battery cell 11 is started (step S204). Consequently, the SOC of the battery cell 11 gradually decreases.

The measurement device 13 periodically acquires the data on the pressure P and the temperature T until the SOC of the battery cell 11 becomes 0% (step S205->No in step S206). That is, the measurement device 13 acquires the data on the pressure P and the temperature T for each of a plurality of SOCs of the battery cell 11.

When the SOC of the battery cell 11 reaches 0% (YES in step S206), the measurement device 13 finishes acquiring the data on the pressure P and the temperature T and calculates, from the acquired data, the SOC characteristics (coefficients) representing the relationship between the pressure P and the SOC at a predetermined temperature (step S207).

The measurement device 13 can determine the SOC characteristics at any temperature by using the calculated temperature characteristics and the SOC characteristics. That is, the measurement device 13 can accurately calculate the SOC of the battery cell 11 from the pressure P regardless of the temperature.

### SOC Measurement During Actual Operations

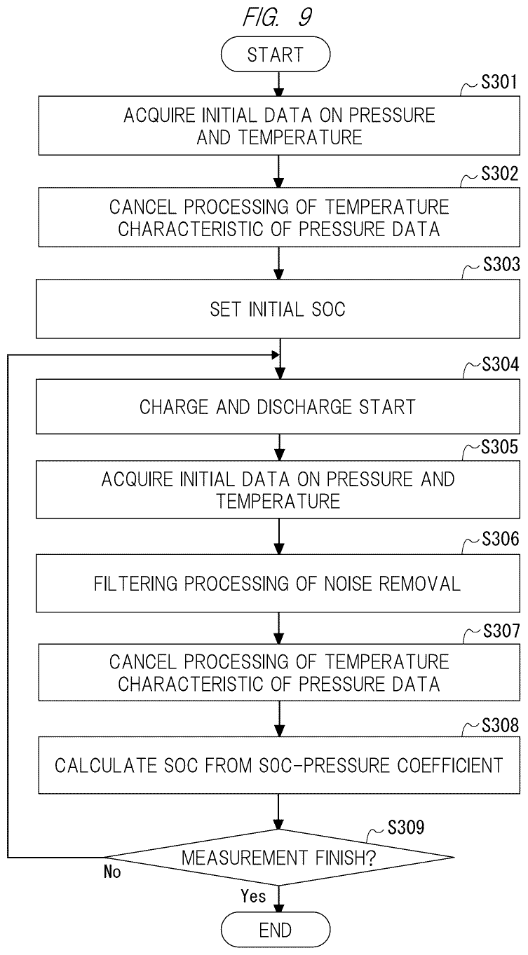

FIG. 9 is a flowchart showing an SOC measurement processing performed by the measurement device 13 during actual operations.

First, the measurement device 13 acquires the data on the pressure P and the temperature T (step S301).

Thereafter, the measurement device 13 performs a cancel processing of the temperature characteristics with respect to the pressure P (step S302). In other words, the measurement device 13 calculates the pressure P by subtracting the error component due to the temperature.

Then, the measurement device 13 calculates the SOC of the battery cell 11 from the pressure P whose temperature characteristics have been canceled, and sets it to an initial value (step S303). Note that, after the initial value of the SOC is set and before the charge/discharge of the battery cell 11 is started, the cancel processing of offsets of the SOC may be performed based on usage statuses of a voltage and a current by using an existing remaining algorithm(s).

Then, the charge and the discharge of the battery cell 11 is started (step S304). For example, when the battery cell 11 is used (discharged), the SOC gradually decreases and when the battery cell 11 is charged, the SOC gradually increases.

Thereafter, the measurement device 13 acquires the data on the pressure P and the temperature T at arbitrary timing (step S305). The arbitrary timing is, for example, timing of starting the charge of the battery cell 11, timing of finishing the charge of the battery cell 11, or the like.

Then, the measurement device 13 performs a filtering processing for removing noise with respect to the acquired data on the pressure P and the temperature T (step S306).

Thereafter, the measurement device 13 performs the cancel processing the temperature characteristics with respect to the pressure P (step S307). In other words, the measurement device 13 calculates the pressure P by subtracting the error component due to the temperature.

Then, the measurement device 13 calculates the SOC from the pressure P whose temperature characteristics have been canceled, and outputs it as a measurement result (step S308). The measurement device 13 repeats the processings of steps S304 to S308 until the measurement is finished (step S309).

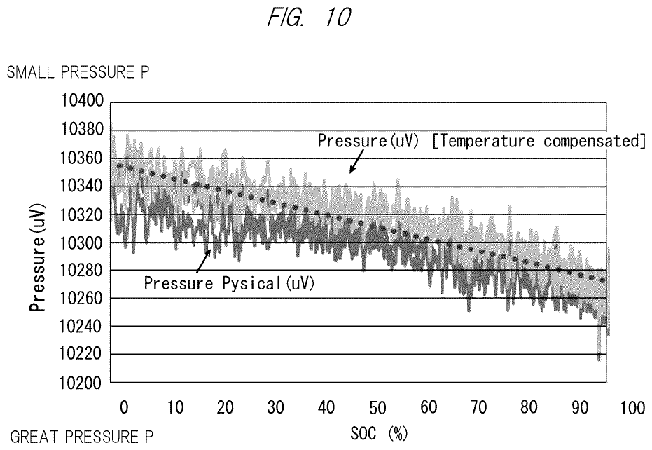

FIG. 10 is a diagram showing a relationship between the pressure P and the SOC of the battery cell 11 before and after the cancel of the temperature characteristics. In FIG. 10, a horizontal axis represents the SOC, and a vertical axis represents the output voltage of the Wheatstone bridge corresponding to the pressure P. Therefore, on the vertical axis, as the output voltage becomes larger, the pressure P becomes smaller (that is, the strain amount S becomes smaller), and as the output voltage becomes smaller, the pressure P becomes larger (that is, the strain amount S becomes larger).

In this way, in the battery device 1 according to the present embodiment, the measurement device 13 calculates the SOC of the battery cell 11, in which the error component due to the temperature has been canceled, by referring to a detection result of the temperature sensor 1315. This makes it possible for the measurement device 13 to accurately calculate the SOC of the battery cell 11 regardless of the temperature in the battery device 1 according to the present embodiment. In particular, in the battery device 1 according to the present embodiment, the battery cell 11 and the measurement device 13 are arranged close to each other and the battery cell 11 and the measurement device 13 are thermally coupled by the coupling member 14, so that it can be assumed that the battery cell 11 and the measurement device 13 operate under substantially the same temperature conditions. As a result, the burden of the arithmetic processing necessary for cancelling the error component of the SOC due to the temperature is reduced in comparison with a case where the battery cell 11 and the measurement device 13 operate under mutually different conditions.

Furthermore, in the battery device 1 according to the present embodiment, since the battery cell 11 and the measurement device 13 are arranged close to each other, a length of a wiring between the strain gauge 12 attached to the battery cell 11 and the measurement device 13 becomes short. As a result, disturbance noise is suppressed, and the detection accuracy of the strain gauge 12 is improved. Further, in the battery device 1 according to the present embodiment, even when the battery cell 11 is repeatedly charged and discharged at the intermediate SOC, there is no error accumulation such as current integration, so that the measurement accuracy of the SOC by the measurement device 13 is stable.

In the battery device 1 according to the present embodiment, the measurement device 13 can be configured so as to remove a strain component caused by gas generation from the strains (corresponding to the pressure P) detected by the strain gauge 12 and extract only an electrode expansion strain component therefrom. Consequently, the measurement device 13 can accurately measure the SOC of the battery cell 11. Hereinafter, a method of removing the strain component caused by the gas generation from the strains detected by the strain gauge 12 and extracting only the electrode expansion strain component therefrom will be specifically described.

First, the measurement device 13 stores a gain a and an offset b of a pressure characteristic approximation equation Y=ax+b obtained in advance in a table TB as an initial setting. Y represents the strain amount in the strain gauge 12, and x represents the SOC of the battery cell 11. The strain amount may be read as the pressure P.

Thereafter, for example, the battery cell 11 is discharged. Here, when the discharge of the battery cell 11 ends with the SOC being below a predetermined rate (for example, 30%), the measurement device 13 acquires data on an OCV and the strain amount after a certain period of time has passed. Note that OCV is an abbreviation for Open Circuit Voltage, and represents an open circuit voltage of the battery cell 11.

Thereafter, the measurement device 13 calculates the SOC of the battery cell 11 from the obtained OCV with reference to a table representing a relationship between the OCV and the SOC.

Then, the measurement device 13 substitutes the acquired strain amount for Y with respect to an equation b=−ax−Y obtained by equation-converting an approximation expression of the pressure characteristic and substitutes the calculated SOC for x, thereby calculating the offset (intercept) b.

Thereafter, the measurement device 13 stores the calculated offset b in a first FIFO buffer. Then, the measurement device 13 calculates an average value bA of a plurality of offsets b stored in the first FIFO buffer (that is, a movement average value of the offsets b).

Then, for example, the battery cell 11 is charged. Here, when the charge of the battery cell 11 is finished with the SOC being at a predetermined rate (for example, 90%) or more, the measurement device 13 acquires data on the OCV and the strain amount after a certain period of time has passed.

Thereafter, the measurement device 13 calculates the SOC of the battery cell 11 from the acquired OCV with reference to the table representing the relationship between the OCV and the SOC.

Then, the measurement device 13 substitutes the acquired strain amount for Y with respect to an equation b=−ax−Y obtained by equation-converting an approximation expression of the pressure characteristic and substitutes the calculated SOC for x, thereby calculating the offset (intercept) b′.

Thereafter, the measurement device 13 substitutes the calculated offset b′ for b and substitutes x for “1”, which the SOC represents as 100%, with respect to the approximate expression Y=ax+b of the pressure characteristics, thereby calculating the strain amount Y of the strain gauge 12 when the SOC is 100%.

Thereafter, the measurement device 13 stores the calculated strain amount Y in a second FIBO buffer. Then, the measurement device 13 calculates an average value YA of a plurality of strain amounts Y stored in the second FIFO buffer (that is, a movement average value of the strain amount Y of the strain gauge 12 when the SOC is 100%).

Then, the measurement device 13 compares the movement average value bA and the offset b stored in the table TB, and if a difference therebetween is larger than or equal to a predetermined value, the measurement device 13 updates the offset b stored in the table TB to a value of the movement average value bA.

Thereafter, the measurement device 13 substitutes the movement average value bA for b and substitutes the movement average value YA for Y with respect to the approximate expression Y=ax+b of the pressure characteristics, thereby calculating a gain (slope) a. Here, the measurement device 13 compares the calculated gain a and the gain a stored in the table TB and if a difference therebetween is larger than or equal to a predetermined value, the measurement device 13 updates the gain a stored in the table TB to a new gain.

Thereafter, the measurement device 13 repeats a processing subsequent to the initial setting.

Here, by updating the offset b and the gain a stored in the table TB, a detection error(s) of the strain amount (that is, the pressure P) due to the strain gauge 12 together with a pressure increase caused by gas generation in the battery cell 11 is suppressed. Note that the update of the offset b is limited only to, for example, a case of a decrease thereof. Further, the update of the gain a is limited to, for example, a case of an increase thereof. However, if the strain gauge 12 is connected to a lower side of the Wheatstone bridge (that is, on a resistance element R4 side), the update of the offset b is limited only to a case of the increase thereof, and the update of the gain is limited only to a case of the decrease thereof.

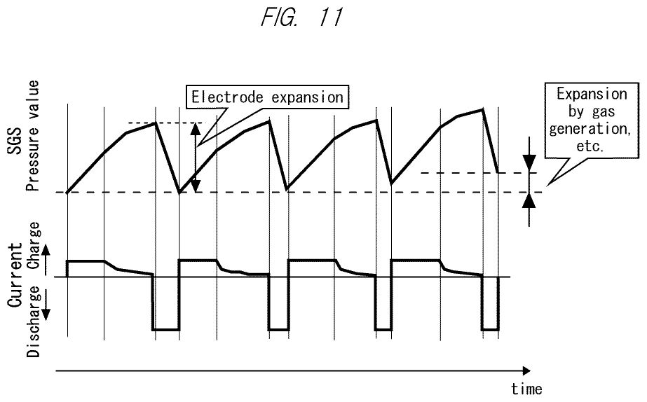

FIG. 11 is a timing chart showing a change in the pressure P that the strain gauge 12 receives from the battery cell 11 repeatedly charged and discharged. Note that in addition to the change in pressure P, FIG. 11 also shows a change in the current flowing through the battery cell 11. As shown in FIG. 11, when the battery cell 11 is repeatedly charged and discharged, gas is generated in the battery cell 11 due to time deterioration and the internal pressure of the battery cell 11 rises. In other words, when the battery cell 11 is repeatedly charged and discharged, the pressure P detected by the strain gauge 12 becomes higher (time t10) than the initial state (time to), for example, even when the battery cell 11 is completely discharged. Therefore, by updating the offset b and the gain a stored in the table TB as described above, the detection error of the strain amount (that is, the pressure P) due to the strain gauge 12 together with the pressure increase caused by the gas generation in the buttery cell 11 is suppressed.

Note that a configuration for removing the strain components caused by the gas generation in the measurement device 13 is not limited to the above-mentioned configuration, and can appropriately be changed to other configurations having equivalent functions. For example, the measurement device 13 has only to be configured so as to update the pressure stored in the database to a pressure value detected by the strain gauge when a difference between the pressure stored in the database (table) and the pressure detected by the strain gauge is equal to or larger than a predetermined value in a case where all of the SOC and the temperature are the same condition(s). Note that the pressure P detected by the strain gauge 12 corresponds to the strain amount detected by the strain gauge 12.

Furthermore, in the battery device 1 according to the present embodiment, the measurement device 13 may include a table storing information representing the relationship between the strain amount S (pressure P) and the SOC for each cell structure of the battery cell.

### Second Embodiment

In this embodiment, an example of a layout of the strain gauges 12 attached to the battery cell 11 will be described. Note that the strain gauge 12 being attached to the battery cell 11 includes the strain gauge 12 being formed integrally with the battery cell 11.

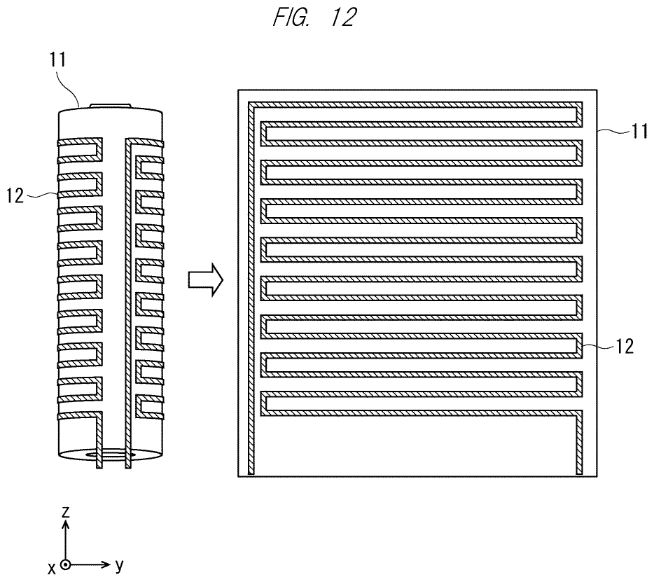

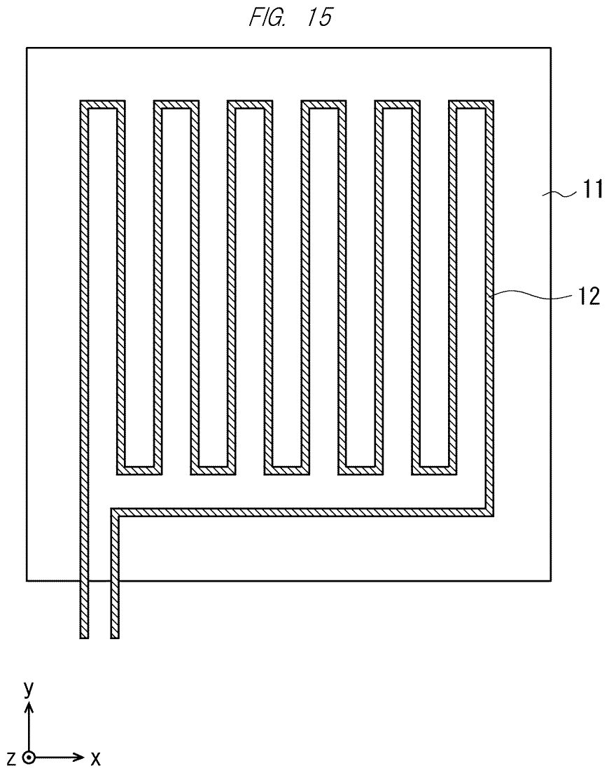

FIGS. 12 to 16 are diagrams each showing an example of layout of the strain gauges 12 attached to the battery cell 11. FIGS. 12 to 14 each show an example of the layout of the strain gauges 12 attached to a side surface of the cylindrical battery cell 11. Note that FIG. 12 also shows an exploded view of the side surface of the battery cell 11. FIG. 15 shows an example of a layout of the strain gauges 12 attached to a main surface of the laminate-shaped battery cell 11.

In an example of FIG. 12, the strain gauge 12 is attached to the side surface of the cylindrical battery cell 11 so as to become longer along a circumferential direction (direction on the x-y plane) than along an axial direction (z-axis direction) of the battery cell 11. Here, the battery cell 11 changes more easily in a radial direction (any direction on the x-y plane) than in the axial direction (z-axis direction) according to the volume expansion during the charge. Therefore, by attaching the strain gauge 12 as in the example shown in FIG. 12, deformation of the battery cell 11 can be detected more sensitively.

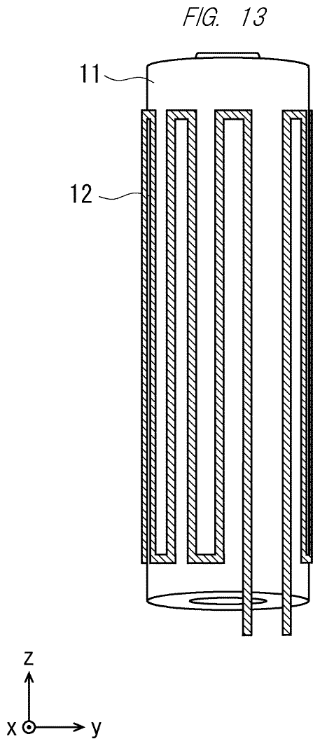

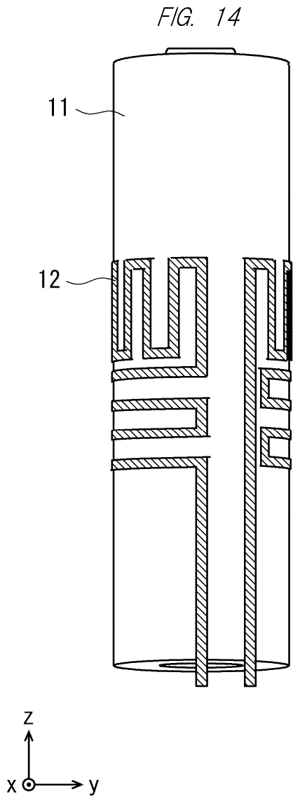

In an example of FIG. 13, the strain gauge 12 is attached to the side surface of the cylindrical battery cell 11 so as to become longer along the axial direction than along the circumferential direction of the battery cell 11. Moreover, in an example of FIG. 14, the strain gauge 12 is attached to the side surface of the cylindrical battery cell 11 so that a length in the axial direction and a length in the circumferential direction of the battery cell 11 are equal to each other.

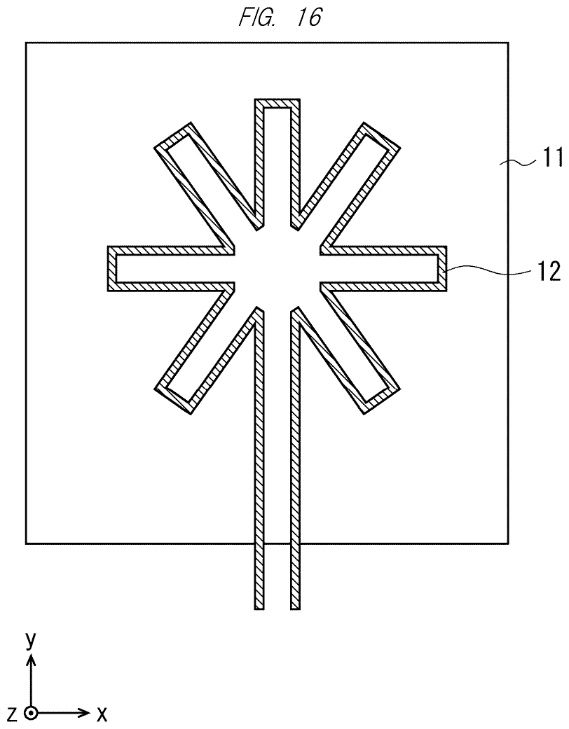

In an example of FIG. 15, the strain gauge 12 is attached to the main surface of the laminated battery cell 11 so as to be elongated along a first direction (for example, the y-axis direction). Note that the strain gauge 12 may be attached to the main surface of the laminated battery cell 11 so that the length in the first direction (for example, the y-axis direction) and the length in the second direction (for example, the x-axis direction) orthogonal to the first direction are equal to each other. Alternatively, as shown in an example of FIG. 16, the strain gauges 12 may be attached radially.

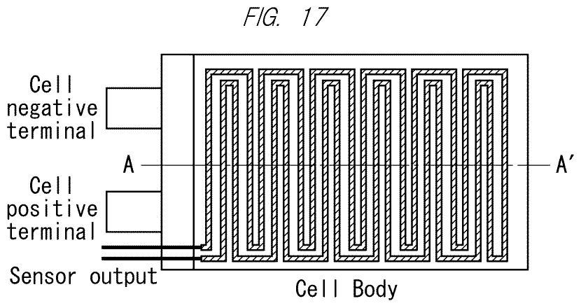

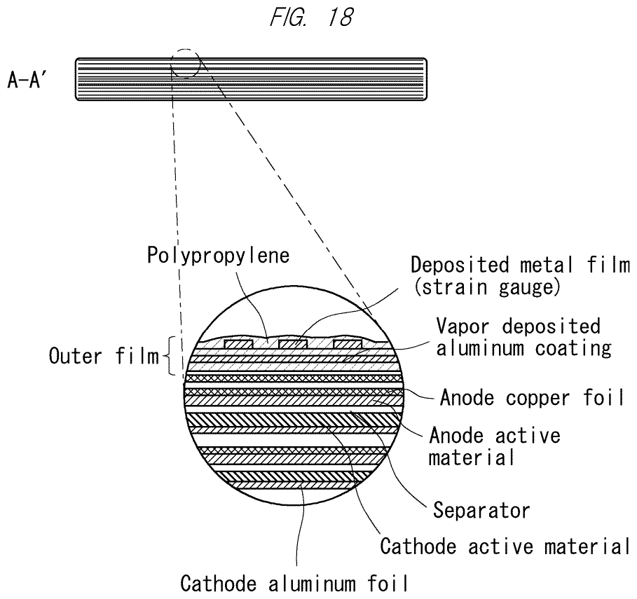

FIG. 17 is a diagram showing an appearance of the laminate-shaped battery cell 11. FIG. 18 is a diagram showing an internal structure of the laminate-shaped battery cell 11. As shown in FIGS. 17 and 18, by printing (vapor deposing) on an exterior film of the laminated battery cell 11, the strain gauge 12 may be integrally formed on the exterior film. Consequently, in comparison with a case of attaching the strain gauge 12 separately, an increase in costs is suppressed and a yield of the product is improved.

As described above, in the battery device 1 according to the embodiment described above, the measurement device 13 calculates the SOC of the battery cell 11, in which the error component due to the temperature has been canceled, by referring to the detection result of the temperature sensor 1315. This makes it possible for the measurement device 13 to accurately calculate the SOC of the battery cell 11 regardless of the temperature. In particular, in the battery device 1 according to the present embodiment, the battery cell 11 and the measurement device 13 are arranged close to each other, and the battery cell 11 and the measurement device 13 are thermally coupled by the coupling member 14, so that it can be assumed that the battery cell 11 and the measurement device 13 operate under substantially the same temperature conditions and, as a result, as compared with a case where the battery cell 11 and the measurement device 13 open under mutually different conditions, the burden of the calculation processing necessary for canceling the error component of the SOC due the temperature is reduced.

Furthermore, in the battery device 1 according to the embodiment described above, since the battery cell 11 and the measurement device 13 are arranged close to each other, the wiring between the strain gauge 12 attached to the battery cell 11 and the measurement device 13 becomes short and, as a result, the disturbance noise is suppressed and the detection sensitivity of the strain gauge 12 is improved. Further, in the battery device 1 according to the embodiment described above, even when the battery cell 11 is repeatedly charged and discharged at the intermediate SOC, there is no error accumulation such as current integration, so that the measurement accuracy of the SOC by the measurement device 13 is stable.

Although the invention made by the present inventor(s) has been explained based on the embodiments above, the present invention is not limited to the embodiments already described and, needless to say, can variously be modified without departing from the scope thereof.

Further, in the present disclosure, part or all of the processings of the measurement device 13 can be realized by cause a CPU (Central Processing Unit) to execute a computer program(s).

The program described above includes an instruction group (or software code) that, when loaded into the computer, causes the computer to perform one or more of the functions described in the embodiments. The program may be stored in a non-transitory computer readable medium or a tangible storage medium. As not the limit but the example, the computer readable medium or the tangible storage medium includes random-access memory (RAM), read-only memory (ROM), flash memory, solid-state drive (SSD) or other memory techniques, CD-Including ROM, DVD (Digital Versatile Disc), Blu-ray Disc or other optical disc storages, magnetic cassette, magnetic tape, magnetic disc storage or other magnetic storage devices. The program may be transmitted on the transitory computer-readable medium or the communication medium. As not the limit but the example, the transitory computer-readable or the communication media includes electrical, optical, acoustic, or other forms of the propagation signals.

What is claimed is:

1. A battery device comprising:
a lithium-ion battery cell;
a strain gauge attached to a surface of the battery cell;
a temperature sensor configured to detect a temperature of the battery cell; and
a measurement device configured to calculate SOC (State of Charge) of the battery cell based on the temperature detected by the temperature sensor and a strain amount of the strain gauge changed according to a volume change due to charge and discharge of the battery cell.

2. The battery device according to claim 1, further comprising a coupling member thermally coupling the battery cell and the measurement device.

3. The battery device according to claim 2,
wherein the coupling member contains at least any of silicone, silicone, and acrylic.

4. The battery device according to claim 1,
wherein the battery cell has a cylindrical shape, and
wherein the strain gauge is attached to a side surface of the battery cell along a circumferential direction.

5. The battery device according to claim 1,
wherein the battery cell has a cylindrical shape, and
wherein the strain gauge is attached to a side surface of the battery cell so as to become longer along a circumferential direction than along an axial direction of the battery cell.

6. The battery device according to claim 1,
wherein the battery cell has a cylindrical shape, and
wherein the strain gauge is attached to a bottom surface of the battery cell.

7. The battery device according to claim 1,
wherein the strain gauge is attached to a bottom surface on a negative electrode side of the battery cell.

8. The battery device according to claim 1,
wherein the battery cell has a laminate shape, and
wherein the strain gauge is integrally formed with an exterior film of the battery cell.

9. The battery device according to claim 1,
wherein the battery cell has a laminate shape, and
wherein the strain gauge is attached to a main surface of the battery cell.

10. The battery device according to claim 1,
wherein the battery cell has a laminate shape, and
wherein the strain gauges are attached radially to a main surface of the battery cell.

11. The battery device according to claim 1,
wherein the battery cell has a laminate shape, and
wherein the strain gauge is attached to a main surface of the battery cell so that a length in a first direction and a length in a second direction perpendicular to the first direction become equal.

12. The battery device according to claim 1, further comprising a database storing information representing a relationship between a strain amount of the strain gauge corresponding to a temperature detected by the temperature sensor and the SOC of the battery cell, and
wherein the measurement device extracts the SOC according to the temperature detected by the temperature sensor and the strain amount of the strain gauge from the database, and outputs it as a measurement result.

13. The battery device according to claim 12,
wherein when a result obtained by comparing a strain amount stored in the database and the strain amount of the strain gauge satisfies a predetermined condition in a case where the SOC and the temperature is both a same condition, the measurement device updates the strain amount stored in the database to a value of the strain amount of the strain gauge.

14. The battery device according to claim 1, further comprising a casing,
wherein the battery cell, the strain gauge, and the measurement device are all provided inside the casing.

15. A control method for a batter device comprising a lithium-ion battery cell, a strain gauge attached to a surface of the battery cell and a temperature sensor, the method comprising:
detecting a temperature of the battery cell by the temperature sensor;
detecting a strain amount of the strain gauge changed according to a volume change due to charge and discharge of the battery cell;
calculating SOC (State Of Charge) of the battery cell based on the temperature of the battery cell and the strain amount of the strain gauge.

16. The control method according to claim 15,
wherein in the step of calculating the SOC of the battery cell, further comprising:
extracting the SOC according to the temperature detected by the temperature sensor and the strain amount of the strain gauge from a database storing information representing a relationship between the strain amount of the strain gauge and the SOC of the battery cell corresponding to the temperature detected by the temperature sensor; and outputting the SOC as a calculation result.

17. The control method according to claim 16,
wherein when the SOC and temperature are both the same conditions and if a result of comparing the strain amount stored in the database with the strain amount of the strain gauge satisfies a predetermined condition, the control method includes updating the strain amount stored in the database to a value of the strain amount of the strain gauge.

18. A computer readable storage medium causing a computer to perform a control processing for a battery device comprising a lithium-ion battery cell, a strain gauge attached to a surface of the battery cell and a temperature sensor,
the computer readable storage medium causing the computer to perform:
a processing of detecting a temperature of the battery cell by the temperature sensor;
a processing of detecting a strain amount of the strain gauge changed according to a volume change due to charge and discharge of the battery cell;
a processing of calculating SOC (State Of Charge) of the battery cell based on the temperature of the battery cell and the strain amount of the strain gauge.

19. The computer readable storage medium according to claim 18,
wherein in the processing of calculating the SOC of the battery cell, further comprising:
a processing of extracting the SOC according to the temperature detected by the temperature sensor and the strain amount of the strain gauge from a database storing information representing a relationship between the strain amount of the strain gauge and the SOC of the battery cell corresponding to the temperature detected by the temperature sensor; and outputting it as a calculation result.

20. The computer readable storage medium according to claim 19,
wherein when the SOC and the temperature are both the same conditions and if a result of comparing the strain amount stored in the database with the strain amount of the strain gauge satisfies a predetermined condition, the computer readable storage medium further causes the computer to perform a processing of updating the strain amount stored in the database to a value of the strain amount of the strain gauge.
